(19) United States
(12) Patent Application Publication
(10) Pub. No.: US 2012/0274324 A1
(43) Pub. Date: Nov. 1, 2012

(54) IMPROVED NMR MEASUREMENT BASED ON ANTIPHASE SIGNALS

(75) Inventors: Kerstin Muennemann, Monzernheim (DE); Jan Falk Frederik Dechent, Mainz (DE); Laura Maria Schreiber, Mainz (DE); Hans Wolfgang Spiess, Mainz (DE)

(73) Assignee: MAX-PLANCK-GESELLSCHAFT ZUR FOERDERUNG DER WISSENSCHAFTEN, E.V., MUENCHEN (DE)

(21) Appl. No.: 13/515,401

(22) PCT Filed: Dec. 21, 2009
(86) PCT No.: PCT/EP09/09195

§ 371 Date: Jul. 17, 2012

(51) Int. Cl. G01R 33/44

(52) U.S. Cl. 324/309

(57) ABSTRACT

A method of measuring magnetic resonance properties of an object, which includes a thermally polarized substance and a contrast agent exhibiting a nuclear magnetic resonance (NMR) antiphase signal (A), comprises the steps of subjecting the object in a stationary magnetic field to an excitation sequence including excitation radio frequency pulses, collecting NMR signals generated in the object including a background signal (B) generated by the thermally polarized substance and the antiphase signal (A) generated by the contrast agent, and reconstructing the magnetic resonance properties of the object based on the NMR signals, wherein the NMR signals are collected during the occurrence of the antiphase signal (A) and with a time delay relative to a maximum of the background signal (B). Furthermore, a measuring device for measuring magnetic resonance properties of an object, like an NMR spectrometer or an MRI device, is described.

### SUBJECT OF THE INVENTION

The present invention relates to a method of measuring magnetic resonance properties of an object including a contrast agent exhibiting nuclear magnetic resonance (NMR) antiphase signals like e.g. a NMR spectroscopy method and/or a magnetic resonance imaging (MRI) method. Furthermore, the present invention relates to a measuring device, which is configured for measuring magnetic resonance properties of an object which includes a contrast agent exhibiting NMR antiphase signals, like e.g. NMR spectrometer or an MRI device.

### TECHNICAL BACKGROUND

It is generally known to investigate objects with NMR spectroscopy or MRI techniques, e.g. in the field of medical imaging. A major issue occurring in molecular or metabolic imaging is the detection of a small amount of molecules of interest which is often concealed by the large background signal of the body. In NMR and MRI applications of molecular or metabolic imaging many efforts were taken to overcome this problem by artificially enhancing the NMR/MRI signal of the molecules of investigation by orders of magnitude by different hyperpolarization techniques, thereby improving the contrast to the thermally polarized bulk nuclei.

The application of hyperpolarized contrast agents in MRI significantly increased during the last decade (see K. Golman et al. in Magn. Reson. Med. 2001, 46, 1-5; H. Johannesson et al. in C. R. Physique 2004, 5, 315-324; M. Goldman et al. in C. R. Chimie 2006, 9, 357-363; S. Mansson et al. in Eur. Radiol. 2006, 16, 57-67; K. Golman et al. in Cancer Res. 2006, 66, 10855-10860; P. Bhattacharya et al. in J. Magn. Reson. 2007, 186, 150-155; and F. A. Gallagher et al. in Nature 2008 453, 940-943). They offer a great advantage over conventional contrast agents because they are the direct signal source and do not rely on implied T1, T2 or T2* changes on the surrounding liquid or tissue as classical Gadolinium-based contrast agents.

A very exciting medical application of hyperpolarized molecules is molecular or metabolic imaging, i.e. to improve tumor diagnosis or therapy monitoring. Malignant tissue can be differentiated from healthy organs on the basis of different metabolic pathways within the citrate cycle. As a consequence, the NMR signal intensity of lactate after injection of hyperpolarized ¹³C-pyruvate is significantly elevated in cancer when compared to normal tissue (see K. Golman et al. in PNAS 2003, 100, 18, 10435-10439; and S. J. Nelson et al. in Appl. Magn. Reson. 2008, 34, 533-544). Recently, in vivo pH mapping after injection of hyperpolarized bicarbonate has been demonstrated for tumor visualization (see F. A. Gallagher et al. cited above).

Furthermore, hyperpolarized components are well suited for perfusion measurements, because the quantification of blood flow through the organ of interest (in ml/min/g tissue) is simplified as compared to the usage of Gadolinium-based contrast agents: for hyperpolarized compounds the signal increase because of inflowing contrast agents depends linearly on contrast agent concentration, which is not the case for Gd-based contrast agents at high concentrations. Of course, reductions of the hyperpolarized signal due to rf pulses and T1 relaxation has to be taken into account (see S. Mansson et al. cited above). The usage of hyperpolarized hetero nuclei (especially ¹³C and ¹⁵N) for in vivo diagnostic MRI applications has been described in U.S. Pat. No. 6,574,495, U.S. Pat. No. 6,574,496, U.S. Pat. No. 5,184,076, and US 2004 0024307 A1.

So far, medical imaging with hyperpolarized compounds was realized with ¹³C or ¹⁵N hyperpolarized substances, which have the advantage of very long T1 times and large chemical shift ranges. The hyperpolarization can be achieved via a number of different techniques, namely Dynamic Nuclear Polarisation (DNP) (see A. Abragam et al. in Rep. Prog. Phys. 1978, 41, 395-467; J. H. Ardenkjaer-Larsen et al. in P. Natl. Acad. Sci. USA 2003, 100(18), 10158-10163; E. R. McCarney et al. in P. Natl. Acad. Sci. USA 2007, 104(6), 1754-1759; and K. Munnemann et al. in Appl. Magn. Reson. 2008, 34, 321-330), Photochemically Induced Dynamic Nuclear Polarization (PhotoCIDNP) (see P. J. Hore et al. in Prog. Nucl. Mag. Res. Sp. 1993, 25, 345-402 and J. Bargon et al. in Helv. Chim. Acta 2006, 89, 2522-2532, and Parahydrogen Induced Polarisation (PHIP) (see C. R. Bowers et al. in J. Am. Chem. Soc. 1987, 109, 5541-5542; T. C. Eisen-schmid et al. in J. Am. Chem. Soc. 1987, 109, 8089-8091; J. Natterer et al. in Prog. Nucl. Magn. Reson. Spectrosc. 1997, 31, 293-315; S. B. Duckett et al. in Prog. Nucl. Magn. Reson. Spectrosc. 1999, 34, 71-92; C. R. Bowers in Encyclopedia of Nuclear Magnetic Resonance, Advances in NMR, vol. 9 (Eds: D. M. Grant, R. K. Harris), John Wiley & Sons. Ltd.: Chichester, 2002, 750-769; K. V. Kovtunov et al. in Angew. Chem. Int. Ed. 2008, 47, 1492-1495; and M. Roth et al. in Magn. Reson. Chem. 2008, 46, 713-717).

Whereas DNP uses the large polarization of unpaired electrons, which is transferred to nuclear spins by microwave irradiation, PHIP is a technique to produce hyperpolarized samples via a chemical route as schematically illustrated in FIG. 7 (prior art). It makes use of the parahydrogen symmetry breaking during homogeneously catalyzed hydro-genation of unsaturated substrates, creation of non-equivalent product protons and the re-insertion of parahydrogen spin information into the substrate molecule.

Parahydrogen, which is the thermodynamically preferred spin isomer of the hydrogen molecule (as opposed to orthohydrogen) can be enriched by cooling under the effect of a paramagnetic catalyst (e.g. charcoal). After a subsequent homogeneous parahydrogenation reaction, PHIP NMR experiments lead to absorption and emission signals and a theoretical signal increase of up to 10⁴, which is in practice limited by relaxation processes. If the hydrogenation is conducted at low magnetic field, followed by transfer into the NMR magnet and subsequent spectra acquisition, the experiment is referred to as Adiabatic Longitudinal Transport After Dissociation Engenders Nuclear Alignment (ALTADENA), leading to signals either in net absorption or emission. If the hydrogenation and NMR measurement are carried out in high field, it is termed Parahydrogen And Synthesis Allow Dramatically Enhanced Nuclear Alignment (PASADENA), leading to characteristic antiphase signals exhibiting both absorption and emission of the NMR resonances resulting from the respective protons (see C. R. Bowers et al. in J. Am. Chem. Soc. 1987, 109, 5541-5542).

In the case of PHIP, the parahydrogen atoms that are introduced in an unsaturated educt carry the hyperpolarization in the first place. Their polarization can be transferred to hetero nuclei by applying field cycling techniques (see M. Stephan at al. in Magn. Reson. Chem. 2002, 40, 157-160) or adequate pulse sequences (see M. Haake at al. in J. Am. Chem. Soc. 1996, 118, 8688-8691; and M. Goldman et al. in C. R. Physique 2005, 5, 575-581). However, the transfer of polarization might introduce some losses due to imperfections, therefore it would be beneficial to use the produced ¹H alignment directly. There arise two problems, if ¹H PHIP polarized molecules should be used for imaging purposes: the Parahydrogen Induced Polarization creates an antiphase proton signal, that might cause artifacts in the images and the T1 of protons is in the range of a few seconds for most molecules causing a fast loss of the hyperpolariza-tion. The first concern was cleared by applying gas phase PHIP imaging in order to follow the hydrogenation reaction in heterogeneous fixed bed catalysts reactors (see L.-S. Bouchard et al. in Science 2008, 319, 442-444; and I. V. Koptyug et al. in J. Am. Chem. Soc. 2008, 130(32), 10452-3) resulting in distortion free images of the hyperpolarized gases with very good SNR. However, the spatial resolution was poor due to the fast diffusion of the molecules in the gas phase.

The conventional techniques of using hyperpolarized substances have a general disadvantage in terms of low signal-to-noise ratio (SNR) or contrast in spectroscopy or imaging. Especially for the most widely used NMR and MRI nuclei—the proton—, the conventional strategy is very limited because of the enormous number of thermally polarized background protons which give rise to a NMR signal of comparable amplitude as the small amount of hyperpolarized protons.

Furthermore, most hetero nuclei (especially ¹³C and ¹⁵N) have a low gyro magnetic ratio which makes it difficult to provide images with high spatial resolution because the gradient strengths of conventional MRI systems is limited and usually optimized for protons. Moreover, additional coils and broadband amplifiers for hetero nuclei are required, which are provided by only few commercial sources, which makes MRI of hetero nuclei very costly and due to the development of new pulse sequences very time consuming.

If hyperpolarized ¹³C is applied for metabolic or perfusion imaging, an additional proton image has to be acquired in order to provide anatomical information. Optimal co-registration of the ¹H and ¹³C images requires the application of a coil which is double resonant for protons and e.g. ¹³C, which is technically demanding and expensive.

### Objective of the Invention

The objective of invention is to provide an improved method of measuring magnetic resonance properties avoiding disadvantages of conventional magnetic resonance techniques. In particular, the objective of invention is providing an improved measuring method being capable of providing magnetic resonance properties, like e.g. spectroscopic and/or image properties with improved SNR or improved contrast. Another objective of invention is to provide an improved magnetic resonance measuring device being capable of avoiding disadvantages of conventional techniques.

These objectives are solved with method and/or devices comprising the features of the independent claims. Preferred embodiments of the invention are defined in the dependent claims.

### SUMMARY OF THE INVENTION

According to a first aspect of the invention, the above objective is solved by a method of measuring magnetic resonance properties of an object, which includes a thermally polarized substance, like e. g. water, and a contrast agent exhibiting a nuclear magnetic resonance antiphase signal. The method comprises the following steps. The object is arranged in a stationary magnetic field and subjected to at least one excitation sequence including excitation radiofrequency pulses. In response to the excitation radiofrequency pulses, NMR signals are generated in the object, which NMR signals include contributions from the thermally polarized substance (background signal) and from the contrast agent (antiphase signal). The inventors have found that the background signal and the antiphase signal have different evolutions in time. The antiphase signal is developing after a decrease of the background signal only. Therefore, according to the invention, the NMR signals are collected at an echo time during the occurrence of the antiphase signal and with a time delay relative to a maximum of the background signal. On the basis of the collected NMR signals, the magnetic resonance properties of the object are reconstructed. Advantageously, a new contrast mechanisms is obtained by collecting NMR signals at a time when the background signal essentially is decayed, so that inherently the signals of the contrast agent are collected.

According to a second aspect of the invention, the above objective is solved by measuring device, like in particular an NMR spectroscopy device or an MRI scanner, for measuring magnetic resonance properties of an object, comprising a main magnetic field device for creating a stationary magnetic field, a transmitter device for creating at least one excitation sequence including excitation radiofrequency pulses, a receiver device arranged for collecting NMR signals generated in the object, and a control device arranged for controlling the receiver device. According to the invention, the control device is adapted for controlling the receiver device such that the NMR signals are collected at a certain echo time during the occurrence of an antiphase signal generated by a contrast agent in the object and with a time delay relative to a maximum of a background signal generated by a thermally polarized substance in the object. Additionally, the measuring device includes a reconstructing circuit for reconstructing the magnetic resonance properties of the object based on the collected NMR signals. Advantageously, the measuring device has a compact structure as a conventional NMR spectrometer or MRI scanner. Disadvantages with regard to a complex hardware as occurring with the conventional imaging using ¹³C and ¹⁵N are avoided.

According to the invention, the object under investigation includes a contrast agent exhibiting a nuclear magnetic resonance antiphase signal. In other words, the contrast agent (contrast molecule) is defined such that it's spectrum in response to the interaction with the excitation radiofrequency pulses (introduction of linearly polarized magnetic field at the Lamor frequency) includes sequences of alternating emission and absorption lines.

With the invention, a strategy is presented to overcome the problems of low signal-to-noise ratio (SNR) or contrast in conventional spectroscopy or imaging which new strategy is based on the different time evolution of antiphase NMR signals compared to normally occurring (inphase) NMR signals. The invention yields a novel MRI/NMR contrast mechanism which allows for the discrimination of a small amount of nuclei exhibiting antiphase NMR signals (as occurring e.g. during Parahydrogen Induced Polarization) from a huge amount of surrounding thermally polarized nuclei. The contrast arises from a time delay of the antiphase signal relative the normal signal and can simply be implemented in any NMR and MRI pulse sequences by applying the minor variation of choosing the optimal echo time for the antiphase signal. Typically, the optimum time delay can be determined by simple test experiments. The new contrast can be applied for e.g. metabolic imaging, perfusion MRI or catheter visualization during MRI guided interventions.

According to a preferred embodiment of the invention, the NMR signals are collected during the occurrence of a maximum amplitude of the antiphase signal. Advantageously, this provides the best SNR or image contrast. Preferably, the NMR signals are collected with a time delay of at least 5 ms, particularly preferred at least 14 ms, e. g. 17 ms after the maximum of the background signal. Preferably, the time delay is below 100 ms. As an advantage, these limits are valid for the contrast agents used in practice. As the background signal occurs immediately after the excitation with the excitation radiofrequency pulses (about 2500 μs for images with slice selection), the echo time at which the NMR signals are collected can be adjusted to be equal to the time delay. Preferably, the control device is adapted for adjusting the echo time according to the above delay and controlling the receiver device such that the NMR signals are collected during the occurrence of the antiphase signal.

According to a further preferred embodiment of the invention, the field strength of the stationary magnetic field can be selected a for obtaining a maximum contrast between the antiphase signal and the background signal. To this end, the control device can be connected with the magnetic field device for setting the field strength of the stationary magnetic field.

As a further advantage, the invention can be implemented with every contrast agent creating the antiphase signal, i.e. even with a contrast agent having a thermally polarized antiphase signal a contrast enhancement is obtained. Thus, the inventive contrast can be used not only for the substance hexyne described below but for every molecule which can be polarized via Parahydrogen Induced Polarization or that can exhibit antiphase NMR signals, which comprises a large amount of biological relevant molecules e.g. succinate (component of the citrate cycle) or barbiturates (anesthetics). This variability concerning molecules and different clinical applications in combination with the simplicity of the inventive method may result in a widespread usage of the inventive contrast for medical diagnosis.

According to a preferred embodiment of the invention, the contrast agent comprises a hyperpolarized substance, particularly preferred a hyperpolarized substance which can be polarized via parahydrogen induced polarization (PHIP). Alternatively, the contrast agent my comprise a hyperpolarized atom, like e. g. ¹³C.

Improved contrast in ¹H Magnetic Resonance Imaging which is based on the antiphase character of PHIP polarized protons enables the provision of a good contrast to normal (thermally polarized) protons even for very small amounts of hyperpolarized substance. Preferred hyperpolarized substances comprise at least one of an unsaturated compound with double or triple bonds, a N-vinylpyrrolinidon compound, a N-acetylenpyrrolidinon compound, an acetylenedicarboxylic acid compound, a dimethylacetylendicarboxylat compound, a maleic acid compound, a succinate compound, a fumarate compound, a barbiturate compound, a hexyne or hexene compound, a TACA (4-Amino-2-butenoic acid) compound, a galatamine compound, a citalopram compound, a dopamine compound, and a hydroxyethylacrylate compound, or at least one derivative thereof.

As a further advantage, there are no limitations in terms of the type of the magnetic resonance property to be obtained with the inventive technique. As preferred examples, at least one of an NMR spectrum and an object image are reconstructed from the collected antiphase signal. Accordingly, the measuring device of the invention is an NMR spectrometer and/or an NMR imaging device (MRI device). For the imaging application, the excitation sequences include the excitation radiofrequency pulses and varying encoding gradients superimposing the stationary magnetic field as it is known from the MRI technique for collecting 2D or 3D object images. As preferred examples, the excitation sequences comprise a FLASH (fast low-angle shot sequence)sequence, a steady-state free precession sequence, like a TrueFISP (True fast imaging with steady state precession) sequence, an EPI (echo planar imaging) sequence or a chemical shift imaging sequence. Preferably, reconstructing an object image can used for at least one of metabolic imaging, molecular imaging, functional MRI, tumor imaging, angiography, flow imaging, perfusion MRI, and catheter visualization.

In particular, the new contrast can be applied for metabolic imaging or perfusion MRI (e.g. using vinylpyrrolinidon, which was already successfully polarized by the inventors) or catheter visualization during MRI guided interventions using only conventional proton pulse sequences and equipment (NMR coils), which reduces the technical demands that arises from MRI of hetero nuclei (non protons e.g. ¹³C, ¹⁵N)

According to a advantageous embodiment of the invention, additionally a reference image of the object based on NMR signals of the object in a contrast agent free condition can be collected. In other words, the reference image is reconstructed on the basis of the NMR signals of thermally polarized molecules (background NMR signals) only. Advantageously, a background-free image of the object can be obtained by subtracting the reference image from the object image. Furthermore, the reference image and the object image can be superimposed in a common image representation allowing the provision of further diagnostic information in medical imaging.

Accordingly, the above disadvantage of using hyperpolarized ¹³C for metabolic or perfusion imaging can be avoided by using PHIP ¹H polarized substances and the inventive contrast mechanism because the signal of the background protons is still visible in the images with optimal (long) echo time which is beneficial for depicting the morphology. However, background free images using the new contrast can be provided by simply acquiring an image with the same imaging parameters of the object before and after injection of the hyperpolarized substances and subsequent subtraction of the two images.

### BRIEF DESCRIPTION OF THE DRAWINGS

Further details and advantages of the invention are described in the following with reference to the attached drawings, which show in:

FIG. 1: a schematic diagram of a preferred embodiment of a measuring device according to the invention;

FIG. 2: a schematic flow chart illustrating features of the measuring method of the invention;

FIG. 3: a reaction scheme for hexyne and para-H₂ resulting in hyperpolarized hexene;

FIGS. 4 to 6: experimental results obtained with the contrast agent hyperpolarized hexene; and

FIG. 7: a schematic illustration of para-hydrogen induced polarisation using a Rhodium (I) catalyst (prior art).

### PREFERRED EMBODIMENTS OF THE INVENTION

Preferred embodiments of the invention are described in the following with particular reference to the collection of antiphase signals at a delayed echo time, wherein exemplary reference is made to the use of hyperpolarized hexene as contrast agent. It is emphasized that the invention can be implemented with other molecules exhibiting nuclear magnetic resonance antiphase signals, including but not only limited to the hyperpolarized molecules as outlined above. Furthermore, exemplary reference is made to the MRI application of the invention. The contrast (or: SNR) enhancing effect of the inventive technique can be obtained correspondingly with the NMR spectroscopy application. Finally, details of NMR spectroscopy or MRI are not described as they are known as such from conventional NMR techniques.

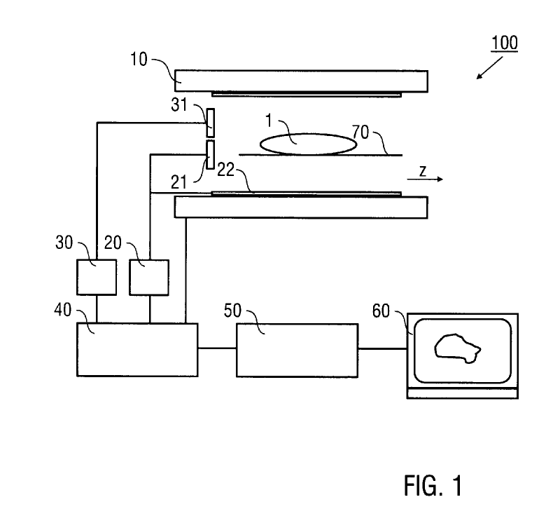

FIG. 1 schematically illustrates a measuring device 100 for magnetic resonance imaging of an object 1, like e.g. a patient or a part thereof or a work piece. The measuring device 100 comprises a main magnetic field device 10, a transmittal device 20, a receiver device 30, a control device 40, a reconstructing circuit 50 and optionally a further data processing device 60. Except of the configuration of the control device 40, these components can be provided as it is known from conventional MRI scanners (like e.g. Magnetom Sonata, Siemens Medical, Erlangen, Germany).

The magnetic field device 10 is arranged for creating a stationary magnetic field in z direction resulting in a netto orientation of the nuclear spins of the molecules in the object 1. The transmitter device 20 is arranged for creating at least one excitation sequence of excitation radiofrequency pulses, which are transmitted via a transmitter coil 21 to the object 1. Additionally, a gradient device 22 is provided, which is configured for creating varying encoding gradients superimposed with the stationary magnetic field. The receiver device 30 is arranged for collecting NMR signals generated in the object 1. It comprises a receiver coil 31. Operation of the transmitter device 20 and receiver device 30 is controlled with the control device 40. In particular, the control device 40 is configured for controlling the excitation sequences created by the transmitter device 20 and the encoding gradients of the gradient device 22 and for receiving the MNR signals collected with the receiver device 30.

The control device 40 is connected with the reconstructing circuit 50, which is configured for an image reconstruction based on the NMR signals. The magnetic resonance image can be further processed (in particular stored, displayed, printed or transmitted to another location) by the data processing device 60.

As an essential feature of the invention, the control device 40 is adapted for adjusting the echo time TE at which the NMR signals are collected with the receiver device. The echo time is adjusted such that the NMR signals are collected in a time range, when maximum antiphase signals of a contrast agent included in the object 1 are detectable, which occurs on the basis of the findings of the inventors with a time delay relative to the background signal as outlined below.

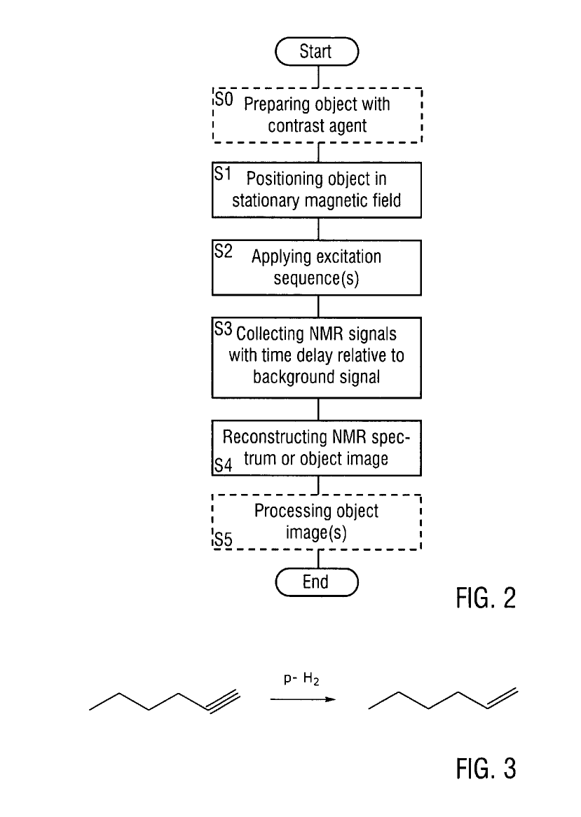

FIG. 2 illustrates the steps of magnetic resonance imaging the object 1 with the measuring device 100, which are further described in the following with reference to particular experimental results. In particular, reference is made to an object 1, which is a sample tube setup described below. Imaging a patient or a part thereof is possible in a corresponding manner.

With a first step (S0 in FIG. 2), the object 1 is prepared with the contrast agent. The contrast agent is produced as follows. For the exemplary embodiment the model substance hexene is used, which is easy to polarize starting from hexyne and para-H₂ (see FIG. 3). For polarizing hexene, normal hydrogen with a purity of 5.0 is used as received from a commercial source (Westfalen AG, Münster, Germany). 98% enriched parahydrogen is generated by cooling normal hydrogen down to 30 Kelvin with a closed-cycle cryostat setup (Advanced Research Systems, Macungie, Pa., USA) in the presence of active charcoal as a catalyst. Parahydrogen can easily be stored for 2-3 days in transportable aluminium cylinders at 3.5 bar. Chemicals are purchased from Sigma-Aldrich and used without further purification.

A typical sample tube setup for the imaging experiments is prepared as follows: 500 mg (6.09 mmol) 1-hexyne and 10 mg (13.8 mmol, 0.23 mol %) [1,4-bis(diphenylphosphino)butane](1,5-cyclooctadiene)rhodium(I) tetrafluoroborate were dissolved in 2600 mg of acetone-d6 (99.9% D) under Argon, filled into a 10 mm screw-cap glass NMR tube and sealed with a septum cap.

Subsequently, the prepared object 1 including the contrast agent is positioned in the measuring device 100 so that it is subjected to the stationary magnetic field (step S1). To this end, the object 1 is arranged on a support device 70 (see FIG. 1), which comprises e.g. a test object holder or a patient table as it is known from conventional MRI scanners. Imaging experiments are performed in a 1.5 Tesla imaging system (Magnetom Sonata, Siemens Medical, Erlangen, Germany). All filter algorithms are deactivated. The resonance frequency, transmitter and shim of the system were calibrated using a water phantom.

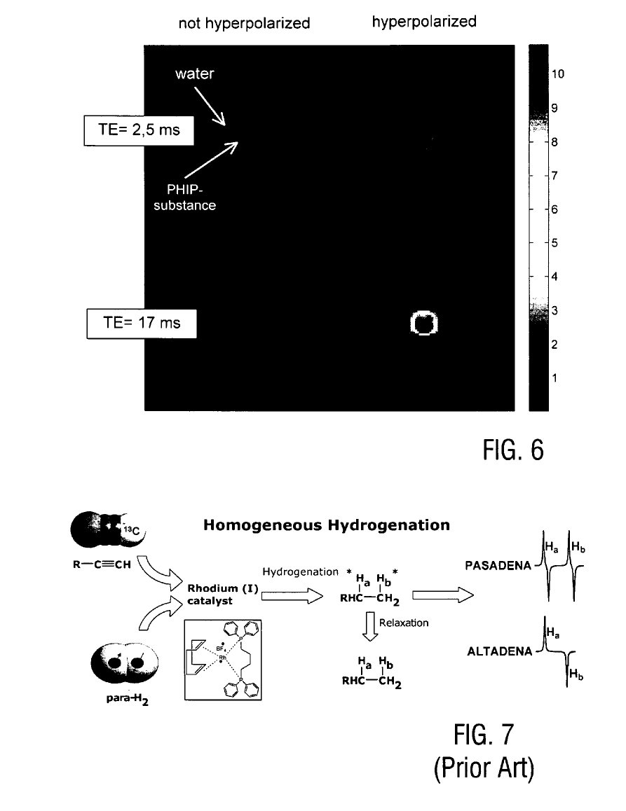

Before the image acquisition, the prepared sample tube is heated up to 60° C. in a water bath and then pressurized with 3.5 bar of enriched p-H₂ from the aluminium cylinder (vide supra) by using syringe techniques outside the tomograph stray field. Subsequently, it is taken carefully into the magnetic field and shaken within the field, thus starting the parahydrogenation reaction by following the conventional “PASADENA under pressure” protocol (see above and FIG. 6). In order to achieve a good filling factor a small loop coil (Siemens Medical, Erlangen, Germany) with 3 cm diameter was used.

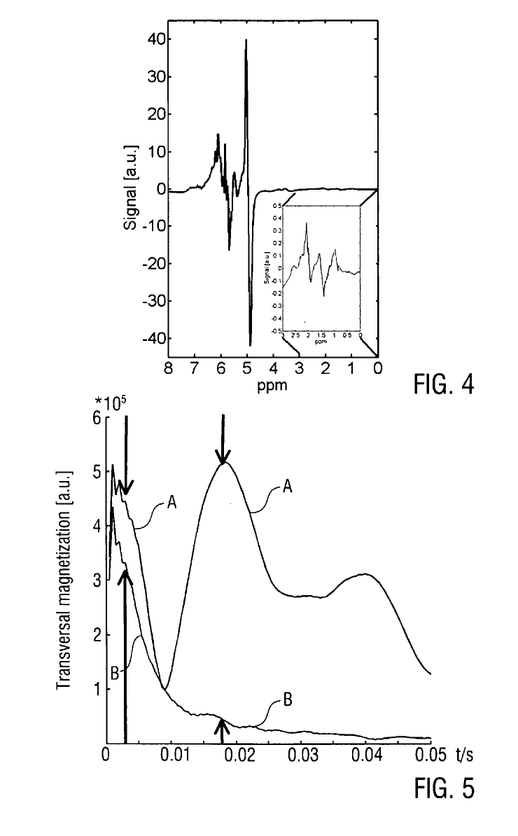

FIG. 4 shows a typical spectrum of hyperpolarized hexene recorded after the para-hydrogenation experiment at 1.5 T. The peaks from 4.5 to 7 ppm originate from 2 hyperpolarized protons, the peaks from 1 to 3 ppm stem from 10 thermally polarized protons. Strong antiphase signals can clearly be observed originating from the hydrogen atoms introduced at C1 and C2 (4.5-7 ppm). The thermally polarized protons (1-3 ppm) are barely visible, the signal enhancement for the inserted protons is ca. 6000.

In order to demonstrate if the hyperpolarized signal can be differentiated from a large proton background signal as it would be the case for in vivo conditions, the 10 mm sample tube which contains the reaction mixture for hyperpolarization is inserted into a 30 mm tube filled with normal water. In FIG. 5 the FID of hyperpolarized hexene (curve A) is shown in comparison to an FID of normal water (curve B). The arrows indicate the echo times that are used for the imaging steps. It can be easily recognized that the FID of the thermally polarized water significantly differs from the FID of hyperpolarized hexene. The water FID shows the normal exponential T2* decay whereas the FID of the hyperpolarized signal reaches its maximum after a time delay of 17 ms. This is due to the fact that the magnetization of the 2 hyperpolarized protons, which feature the strong antiphase signal, interfere in positive or a negative way after an rf pulse (x,y plane) resulting in a temporal modulation of the observable signal.

The image acquisition (steps S2, S3 in FIG. 2) is conducted with multiple echo times for demonstrating the effect of the inventive technique. The results of the imaging (including reconstructing the images, step S4 in FIG. 2) of the sample (10 mm sample tube inserted in 30 mm water tube) are presented in FIG. 6, which show centric reordered FLASH images of a 10 mm tube containing the hyperpolarized substance dissolved in deuterated acetone inserted in 30 mm tube filled with normal water. The left column shows conventional images acquired without the polarization procedure as can be recognized from the low signal of the inner sample tube which originates from the small amount of thermally polarized protons of hexyne. The outer sample tube filled with water shows a much higher MR signal intensity due to the much larger proton abundance. The right column shows images acquired after PHIP polarization. Thus, a bright signal from the hyperpolarized protons in the inner tube can be observed. The top row shows images measured with minimal echo time (TE: 2.5 ms), while the bottom row shows images measured with optimal echo time (TE: 17 ms) for the detection of the antiphase signal. All images were windowed equally. The signal of the water tube is much higher in the images acquired with minimal echo time than in the long echo time images, which can be explained by the exponential decay of the water signal as demonstrated in FIG. 5. However, the signal of the hyperpolarized protons behaves in the opposite way: it shows a huge increase at the long echo time. This can be explained by the different temporal evolution of the hyperpolarized and the thermally polarized signals as can be recognized from FIG. 5.

Optionally, further image processing can be provided (step S5 in FIG. 2), e. g. for the above embodiments of superimposing the object image with a reference image being reconstructed on the basis of background NMR signals only

The features of the invention disclosed in the above description, the drawings and the claims can be of significance both individually as well as in combination for the realization of the invention in its various embodiments.

1. A method of measuring magnetic resonance properties of an object, which includes a thermally polarized substance and a contrast agent exhibiting a nuclear magnetic resonance (NMR) antiphase signal, comprising the steps of:
subjecting the object in a stationary magnetic field to an excitation sequence including excitation radiofrequency pulses,
collecting NMR signals generated in the object including a background signal generated by the thermally polarized substance and the antiphase signal generated by the contrast agent, wherein the NMR signals are collected during an occurrence of the antiphase signal and with a time delay relative to a maximum of the background signal, and
reconstructing the magnetic resonance properties of the object based on the NMR signals.

2. The method according to claim 1, wherein the NMR signals are collected during an occurrence of a maximum amplitude of the antiphase signal.

3. The method according to claim 1, wherein the time delay is at least 5 ms.

4. The method according to claim 1, further comprising the step of selecting a field strength of the stationary magnetic field for obtaining a maximum contrast between the antiphase signal and the background signal.

5. The method according to claim 1, wherein the contrast agent comprises a hyperpolarized substance.

6. The method according to claim 5, wherein the contrast agent comprises a hyperpolarized substance which is adapted to be polarized via parahydrogen induced polarization.

7. The method according to claim 5, wherein the contrast agent comprises at least one member selected from the group consisting of
an unsaturated compound with double or triple bonds,
a N-vinylpyrrolinidon compound or derivative thereof,
a N-acetylenpyrrolidinon compound or derivative thereof,
an acetylenedicarboxylic acid compound or derivative thereof,
a dimethylacetylendicarboxylat compound or derivative thereof,
a maleic acid compound or derivative thereof,
a succinate compound or derivative thereof,
a fumarate compound or derivative thereof,
a barbiturate compound or derivative thereof,
a hexyne or hexene compound or derivative thereof,
a TACA compound or derivative thereof,
a galatamine compound or derivative thereof,
a citalopram compound or derivative thereof,
a dopamine compound or derivative thereof, and
a hydroxyethylacrylate compound or derivative thereof.

8. The method according to claim 1, wherein the contrast agent comprises ¹³C.

9. The method according to claim 1, wherein the magnetic resonance properties comprise at least one of an NMR spectrum and an object image.

10. The method according to claim 9, wherein the excitation sequence comprises a FLASH sequence, a steady-state free precession sequence, an EPI sequence or a chemical shift imaging sequence.

11. The method according to claim 10, further comprising the step of reconstructing a reference image of the object based on NMR signals collected with the object in a contrast agent free condition.

12. The method according to claim 11, further comprising the step of providing a background-free image of the object by subtracting the reference image from the object image.

13. The method according to claim 11, further comprising the step of superimposing the reference image and the object image in a common image representation.

14. The method according to claim 9, wherein reconstructing the object image is used for at least one of metabolic imaging, molecular imaging, functional MRI, tumor imaging, angiography, flow imaging, perfusion MRI, and catheter visualization.

15. A measuring device for measuring magnetic resonance properties of an object, which includes a thermally polarized substance and a contrast agent exhibiting nuclear magnetic resonance (NMR) antiphase signals, comprising:
a main magnetic field device arranged for creating a stationary magnetic field,
a transmitter device arranged for creating excitation sequences including excitation radiofrequency pulses,
a receiver device arranged for collecting NMR signals generated in the object including a background signal generated by the thermally polarized substance and the antiphase signals generated by the contrast agent at an echo time (TE) after each excitation radiofrequency pulse,
a control device arranged for controlling the receiver device, wherein the control device is adapted for controlling the receiver device such that the NMR signals are collected at the echo time (TE) during an occurrence of the antiphase signal and with a time delay relative to a maximum of the background signal. and
a reconstructing circuit arranged for reconstructing the magnetic resonance properties of the object based on the NMR signals.

16. The measuring device according to claim 15, wherein the control device is adapted for controlling the receiver device such that the NMR signals are collected during the occurrence of a maximum amplitude of the antiphase signal.

17. The measuring device according to claim 15, wherein the control device is adapted for controlling the time delay to at least 5 ms.

18. The measuring device according to claim 17, wherein the control device is adapted for controlling the main magnetic field device and for selecting a field strength of the stationary magnetic field for obtaining a maximum contrast between the antiphase signal and the background signal.

19. The measuring device according to claim 15, which is an NMR spectrometer or an MRI device.

20. The method according to claim 1, wherein the time delay is at least 14 ms.

21. The method according to claim 10, wherein the steady-state free precession sequence is a TrueFISP sequence.

22. The measuring device according to claim 15, wherein the control device is adapted for controlling the time delay to at least 14 ms.
